(19) United States
(12) Patent Application Publication
(10) Pub. No.: US 2013/0273725 A1
(43) Pub. Date: Oct. 17, 2013

(54) METHOD OF FABRICATING A STRUCTURED SEMICONDUCTOR SUBSTRATE

(71) Applicant: ALTIS Semiconductor, (US)

(72) Inventors: Jean-Luc Baltzinger, DRAVEIL (FR); Didier Copinet, MENNECY (FR); Patrick Demarest, BOIS LE ROI (FR)

(21) Appl. No.: 13/644,719

(22) Filed: Oct. 4, 2012

(30) Foreign Application Priority Data
Oct. 6, 2011 (FR) 11 59027

(51) Int. Cl. H01L 21/02

(52) U.S. Cl. CPC H01L 21/0243
USPC 438/542

(57) ABSTRACT

A method is provided for fabricating a structured semiconductor substrate including: i) depositing, on the surface of a semiconductor material, a sacrificial layer of material different from the semiconductor material. At step ii), the sacrificial layer, formed in step i) is etched at least in part so as to form sacrificial layer islets on the surface of the semiconductor material. The semiconductor material of step ii) is etched at least in part, in zones that are not protected by said islets, so as to form a structured semiconductor material, this step iii) being performed in the presence of oxygen so as to deposit an oxide layer on the surface of the semiconductor material. The sacrificial layer islets and the oxide layer are eliminated from the surface of the semiconductor material obtained in step iii), so as to form the structured substrate.

### RELATED APPLICATION

This application claims the benefit of priority from French Patent Application No. 11 59027, filed on Oct. 6, 2011, the entirety of which is incorporated by reference.

### BACKGROUND

1. Field of the Invention

The present invention relates to a method of fabricating a structured semiconductor substrate.

It applies typically, but not exclusively, to the field of microelectronics for fabricating electronic components such as, for example: photodetectors, modulators, light emitters, waveguides, photonic band gap filters, optical amplifiers, optical interconnectors, integrated circuits, etc. . . . .

2. Description of Related Art

Certain types of photodetector, like other electronic components, are conventionally fabricated on the basis of silicon by the complementary metal oxide semiconductor (CMOS) method.

Present-day photodetectors fabricated from a silicon substrate are intended to absorb about 60% of visible light, and conventionally they have poor absorption efficiencies in the infrared range. Their field of application therefore remains limited.

Novel structures have appeared in order to broaden the range of applications for that type of technology to a wider spectrum of wavelengths, including the infrared range: reference is made to a micro-structured silicon substrate that is well known under the term “black” silicon (since the silicon is absorbent, it appears black).

In this context, reference may be made to document U.S. Pat. No. 7,390,689, which describes the method of obtaining a micro-structured substrate. That method consists in irradiating the plane surface of a silicon substrate with laser pulses so as to obtain a silicon substrate with a structure that includes cavities having sloping walls, the bottom sections of the cavities being smaller than the top sections of the cavities (each cavity tapers with increasing depth).

Nevertheless, that type of method presents the drawback of being complex to implement and of being difficult to apply on an industrial scale with a high level of productivity.

### OBJECTS AND SUMMARY

The object of the present invention is to mitigate the drawbacks of the prior art, in particular by proposing a method of fabricating a structured semiconductor substrate, which method is simple and inexpensive and suitable for being applied with very great productivity.

The present invention provides a method of fabricating a structured semiconductor substrate, the method comprising the following steps:

i) depositing on the surface of a semiconductor material, a sacrificial layer of material different from the semiconductor material;

ii) etching the sacrificial layer formed in step i) at least in part so as to form sacrificial layer islets on the surface of the semiconductor material;

iii) etching the semiconductor material of step ii), at least in part, in zones that are not protected by said islets, so as to form a structured semiconductor material, this step iii) being performed in the presence of oxygen so as to deposit an oxide layer on the surface of the semiconductor material; and

iv) eliminating the sacrificial layer islets and the oxide layer from the surface of the semiconductor material obtained in step iii), so as to form said structured substrate.

Advantageously, the present invention makes it possible to provide a method of fabricating a structured substrate, or more particularly a micro-structured substrate, which method is easy to implement and can be applied on an industrial scale.

In addition, the structured semiconductor substrate of the invention guarantees excellent optical absorption, in particular for wavelengths lying in the range 600 nanometers (nm) to 2000 nm.

The term “structured” substrate is used to mean a substrate having its surface including sloping-walled cavities, thereby forming an array of cavities.

The array of cavities comprises more particularly several alignments of cavities.

Each of said cavities has a bottom portion and a top portion. The maximum distance between the bottom portion and the top portion defines the depth of a cavity.

The cavities may be U-shaped or they may be V-shaped. When the cavities are U-shaped, the sections of the bottom portions of the cavities are substantially equal to the sections of the top portions of said cavities, such that the cavities are of section that remains constant over their full depth. As a result, they form a substantially uniform assembly in which the alternation between the top and bottom portions of the cavities defines a “crenellated” structure. In other words, the residual portions of semiconductor material (i.e. the semiconductor material that is not eliminated in steps i) to iv)) that constitute the sloping walls of said U-shaped cavities may be of rectangular shape.

When the cavities are V-shaped, the sections of the bottom portions of the cavities are smaller than the sections of the top portions of said cavities, such that the section of each cavity decreases with increasing depth. As a result, the cavities form a substantially uniform assembly in which the alternation between the top and bottom portions of the cavities defines a “sawtooth” or “sinewave” structure. In other words, the residual portions of semiconductor material (i.e. semiconductor material that is not eliminated in steps i) to iv)) that constitute the sloping walls of said V-shaped cavities may be of conical or triangular shape.

The structured substrate of the present invention is more particularly a micro-structured substrate, since the fields of application of a substrate of this type lie in microelectronics.

The depth of the sloping-walled cavities may thus be of the order of a few tens of micrometers, or less than 10 micrometers (μm).

For wavelengths lying in the range 600 nm to 1000 nm, the structured substrate of the present invention advantageously makes it possible to have optical absorption of at least 70%, preferably of at least 80%, more preferably of at least 90%, and in more particularly preferred manner of at least 95%.

For wavelengths lying in the range 1200 nm to 2000 nm, the structured substrate of the present invention advantageously makes it possible to have optical absorption of at least 10%, and preferably of at least 15%.

In the present invention, the optical absorption of a semiconductor substrate can easily be determined by using ellipsometry in the visible and in the infrared, where this technique is well known to the person skilled in the art.

### Step i)

The surface of the semiconductor material of step i) onto which the sacrificial layer is deposited is preferably a surface that is substantially plane.

The semiconductor material includes in particular a top face and a bottom face, the top face being substantially parallel to the bottom face. The top face is in particular a face that is substantially plane.

The thickness of the semiconductor material is preferably sufficient to guarantee that the structured semiconductor substrate retains good stiffness at the end of the fabrication method. For example, the thickness may lie in the range 50 μm to 900 μm.

The semiconductor material may be selected from silicon and germanium. It is preferable to use silicon, and in particular monocrystalline silicon.

The semiconductor material used in step i) may include one or more N-type or P-type doping elements. Doping types are well known to the person skilled in the art. N-type doping elements are generally selected from atoms having five valence electrons, such as atoms from column 15 (VA) of the periodic table of elements. By way of example, mention may be made of phosphorus (P), arsenic (As), and antimony (Sb). P-type doping elements are generally selected from trivalent atoms, such as those from column 13 (IIIA) of the periodic table of elements. By way of example, mention may be made of boron (B).

When the semiconductor material is doped with an N- and/or P-type element, the concentration of doping element(s) within the semiconductor material may lie in the range 1×10¹² atoms per cubic centimeter (atoms/cm³) to 1.5×10¹⁵ atoms/cm³.

The sacrificial layer of the invention may be an electrically conductive layer and/or an electrically insulating layer (i.e. a dielectric layer).

In a preferred implementation, the sacrificial layer is an electrically insulating layer selected from a layer of an oxide and a layer of a nitride.

By way of example, the oxide layer may be a layer of silicon oxide (SiO₂), and the nitride layer may be a layer of silicon nitride (Si₃N₄).

The sacrificial layer may be deposited by methods well known to the person skilled in the art, e.g. such as chemical vapor deposition, in particular low pressure chemical vapor deposition (LPCVD).

In a first variant, the SiO₂ type sacrificial layer may be obtained by gaseous deposition under low pressure (e.g. LPCVD) of tetraethyl orthosilicate (TEOS) having the formula Si(OC₂H₅)₄ onto the surface of the semiconductor material.

In a second variant, the SiO₂ type sacrificial layer may be obtained firstly by gaseous deposition under low pressure (e.g. LPCVD) of a layer of polysilicon onto the surface of the semiconductor material, followed by oxidizing said layer of polysilicon.

Step ii)

The etching of step ii) consists in removing at least in part the sacrificial layer formed in step i), so as to form sacrificial layer islets on the surface of the semiconductor material. Thus, when the etching of step ii) has finished, the sacrificial layer is not completely removed since said sacrificial layer islets remain. In addition, the etching of step ii) makes it possible to avoid removing any significant amount of semiconductor material.

Thus, after step ii), the surface of the semiconductor material on which the sacrificial layer was deposited has zones that are not protected (i.e. zones that are not covered) by sacrificial layer islets, together with zones that are protected (i.e. zones that are covered) by sacrificial layer islets.

The distance between two immediately adjacent islets may be at most 10 μm, and preferably at most 5 μm, with a more particularly preferred distance being of the order of 1 μm to 2 μm.

The etching of step ii) may be essentially physical etching, in particular etching of the anisotropic type (i.e. anisotropic etching).

More particularly, this essentially physical etching is reactive ionic etching.

In a first variant, the sacrificial layer may be etched using a plasma constituted, by an HBr/NF₃/O₂ gas mixture.

In a second variant, the sacrificial layer may be etched using a plasma made from a fluoride gas, e.g. carbon tetrafluoride (CF₄).

Nevertheless, it is preferable to stop this etching before said plasma constituted by a fluoride gas etches the semiconductor material. Systems well known to the person skilled in the art for detecting the end of etching, such as optical spectroscopy, make it easy by analyzing the chemical species present in the plasma to detect, for example, when etching changes from etching the sacrificial layer to etching the semiconductor material.

In a third, variant, the sacrificial layer may be etched using the following successive steps:

depositing a layer of photosensitive resin onto the sacrificial layer;

performing photolithography (e.g. exposure through a mask to determine the layout of the islets, followed by developing the exposed zone) so as to form protective islets of photosensitive resin;

etching the sacrificial layer (where not protected by said protective islets of photosensitive resin) using a plasma made from a fluoride gas such as for example carbon tetrafluoride (CF₄), so as to form sacrificial layer islets protected by said protective islets of photosensitive resin; and

stripping away the protective islets or photosensitive resin.

Step iii)

The etching of step iii) consists in removing at least part of the semiconductor material of step ii) that is not covered by the sacrificial layer islets: said sacrificial layer islets thus serve to protect or “mask” the portions of semiconductor material that they cover. This etching step serves in particular to form sloping-walled cavities having top portions that are covered by said islets.

This step iii) is performed in the presence of oxygen so as to deposit, preferably simultaneously, a layer of an oxide onto the surface of the semiconductor material.

During this step, and because of the presence of oxygen, an oxide layer is deposited onto the surface of the semiconductor material, in particular onto the sloping walls of said cavities, as formed during the etching of step iii). This oxide deposition serves advantageously to obtain cavities of greater or lesser depth.

The depth and the shape of the cavities can thus be modulated by oxide layer deposition as a function of the quantity of oxygen present during etching step iii).

Thus, this step serves to form a structured semiconductor material, in particular a micro-structured semiconductor material.

When the etching of step iii) has finished, the sacrificial layer islets are substantially unaffected, with only the semiconductor material being etched, however it will naturally be understood that it is not all removed.

The implementation of this etching step depends on two parameters, namely etch rate and etch time. Thus, the person skilled in the art can vary at least one of these two parameters.

For example, it is possible:

a) to act on the different etch rates between the sacrificial layer and the semiconductor substrate;

b) to act on etch time, thereby determining cavity depth; and

c) to act on both parameters a and b.

Preferably, in step iii), the rate at which the sacrificial layer is etched away, and more particularly the rate at which the sacrificial layer islets are etched away, is less than the etch rate of the semiconductor material, and preferably the sacrificial layer etch rate is ten times slower them the etch rate of the semiconductor material.

The etching of step iii) may be dry etching, and in particular it may be anisotropic etching, preferably plasma etching of the reactive ionic type.

As examples of dry etching, mention may be made of etching performed using a plasma constituted by an HBr/NF₃/O₂ gas mixture, or by a plasma constituted by an SF₆/O₂ gas mixture.

### Step iv)

Step iv) serves to eliminate at least part and preferably all of the sacrificial layer islets together with the oxide layer present on the surface of the semiconductor material obtained in step iii), so as to form said structured substrate.

In addition, step iv) makes it possible to avoid removing substantially any semiconductor material.

Wet chemical etching is used in conventional manner with a solution of hydrofluoric acid (HF).

The structured substrate as formed in this way is ready for use in subsequent steps of doping, heat treatment, etc. . . . .

As defined above, the structured substrate of the invention is in particular a substrate having a surface that is substantially plane and including sloping-walled cavities, thereby forming an array of cavities.

Each cavity has a bottom portion and a top portion. The maximum distance between the top portion and the bottom portion defines the depth of the cavity.

The maximum distance between two sloping walls in the top portions of the cavities may be no greater than 10 μm, preferably no greater than 5 μm, and in particularly preferred manner about 1 μm to 2 μm.

In particularly advantageous manner, the semiconductor material initially used in step i) is eliminated by more than 50% by volume, preferably more than 70% by volume, more preferably more than 90% by volume, and in more particularly preferred manner by more than 95% by volume, in order to form said cavities, thereby obtaining the structured semiconductor substrate of the invention.

This removal percentage serves to guarantee excellent optical absorption at wavelengths lying in particular in the range 600 nm to 2000 nm.

In particularly advantageous manner, the structured semiconductor substrate obtained after step iv) has a top face that is said to be structured, this structured top face including surface portions of the semiconductor material of step i). These surface portions correspond to the top portions of the cavities.

The structured top face may then comprise at most 50% of the surface of the semiconductor material, preferably at most 30% of the surface of the semiconductor material, preferably at most 10% of the surface of the semiconductor material, and in more particularly preferred manner at most 5% of the surface of the semiconductor material, in order to form said cavities and thus obtain the structured semiconductor substrate of the invention.

The method of fabricating a structured substrate of the invention may also include the following step:

v) doping the substrate obtained in step iv) with a doping element selected from the elements of column 16 (i.e. group VIA) of the periodic table, such as, in particular: sulfur, selenium, and tellurium, or a mixture thereof.

Said step v) serves advantageously to improve significantly the optical absorption of the structured semiconductor substrate of the invention, in particular at wavelengths lying in the range 1200 nm to 2000 nm.

In a first variant, the doping of step v) may be performed by implanting ions of said doping element within the substrate obtained in step iv). This technique consists in bombarding the surface of the structured substrate obtained in step iv) with a beam of ions of said doping element.

In a second variant, the doping of step v) may be performed by diffusing said doping element within the substrate obtained in step iv). Doping is typically performed in an oven, at a temperature lying in the range 850° C. to 1150° C.

Whether in the first variant or the second variant, these two methods of doping are well known to the person skilled in the art.

In a particular implementation, once step v) has been performed, the concentration of doping element within the semiconductor material may lie in the range 1×10¹⁶ atoms/cm³ to 1×10²⁰ atoms/cm³.

The method of fabricating a structured substrate of the invention may also include the following step (after step v):

vi) performing heat treatment to electrically activate the doping element, within the substrate of step v).

The heat treatment step vi) is a “annealing” step, and it is implemented in particular when the first variant of step v) has been performed (i.e. doping by ionic implantation). This step serves advantageously to electrically activate the doping elements implanted in step v), and to reconstruct the crystal lattice of the silicon that is liable to have been damaged during step v).

This step thus encourages spreading of the doping element within the structured substrate.

This step may be performed in particular at a temperature lying in the range 500° C. to 1200° C. (limits included), and preferably in the range 800° C. to 1000° C. (limits included). By way of example, the heat treatment step may be of the conventional thermal annealing type at a temperature of about 800° C. for about 1 hour, or else it may be of the rapid thermal processing (RTP) type at a temperature of about 1000° C. for a few seconds.

### BRIEF DESCRIPTION OF THE DRAWINGS

Other characteristics and advantages of the present invention appear in the light of the following examples described with reference to the annotated figures, which examples and figures are given by way of non-limiting illustration.

FIGS. 1 to 4 are diagrammatic longitudinal section views of a semiconductor substrate fabricated using the method of the invention.

FIG. 5 shows how optical absorption (%) varies as a function of wavelength (nm) for two semiconductor substrates of the invention (C2 and C3), and for a prior art substrate (C1).

FIG. 6 is an image obtained with a scanning electron microscope (SEM) at a magnification of 10,000 times showing the surface of a structured semiconductor substrate obtained by the method of the invention.

### DETAILED DESCRIPTION

For reasons of clarity, elements that are the same are designated using references that are identical. Furthermore, only those elements that are essential for understanding the invention are shown, they are shown in diagrammatic manner, and they are not to scale.

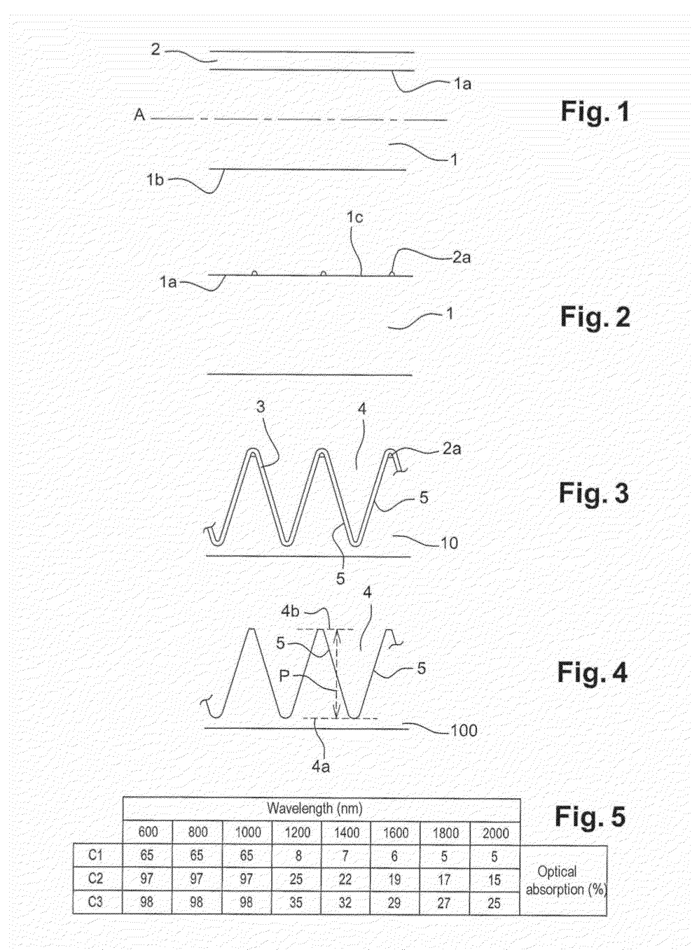

The terms “bottom portion” and “top portion” are not limiting in any way in the context of the present invention, and they serve in particular to make it easier to understand the invention relative to the positioning of the substrate of the invention as shown in FIGS. 1 to 4.

FIG. 1 is a diagrammatic longitudinal section view of a layer of monocrystalline silicon material 1 that is elongate along a longitudinal axis A. It has a top face 1a and a bottom face 1b, the top face 1a being substantially plane.

These two faces 1a and 1b are substantially mutually parallel, and they are spaced apart by a thickness of about 630 μm (i.e. the thickness of the layer of monocrystalline silicon material).

An electrically insulating sacrificial layer 2 of the silicon dioxide type is deposited onto the top surface 1a by LPCVD with a vapor phase of TEOS, at low pressure (step i)).

More particularly, the silicon diode is deposited in an Alpha 8S type oven from Tokyo Electron Limited at a temperature of 650° C. for 1 h25, with TEOS being delivered at a rate of 100 cubic centimeters per minute (cm³/min) at a pressure of 0.25 torr. The resulting sacrificial layer 2 has a thickness of about 130 nm.

Once the sacrificial layer 2 has been deposited, a first etching step (step ii)) is performed that consists in removing at least part of the sacrificial layer 2 without touching the monocrystalline silicon material 1, so as to form sacrificial material islets 2a on the surface 1a of the monocrystalline silicon material 1, as shown in FIG. 2. The surface 1a of the monocrystalline silicon material thus has zones 1c that are not protected or covered by sacrificial layer islets.

This first etching is reactive ionic etching implemented using a plasma made from an HBr/NF₃/O₂ gas mixture.

Once the sacrificial layer islets 2a have been formed, a second etching step (step iii)) is performed consisting in removing at least part of the monocrystalline silicon material 1 from the zones 1c that are not protected by said sacrificial layer islets, but without harming the sacrificial layer islets 2a, so as to form a micro-structured monocrystalline silicon material 10 having cavities 4 with sloping walls 5, as shown in FIG. 3.

In this step, the rate at which the layer 2 of silicon dioxide (i.e. the sacrificial layer islets) is etched is at least ten times slower than the rate at which the monocrystalline silicon material 1 is etched.

This second etching step is dry etching consisting in placing the monocrystalline silicon with said sacrificial layer islets in a reactor in order to process it with a plasma of an HBr/NF₃/O₂ gas mixture. During this second etching step, a layer 3 of silicon oxide becomes deposited simultaneously onto the surfaces of the resulting sloping walls (i.e. the silicon oxide deposit grows). The silicon dioxide layer as deposited in this way is about 100 nm thick (thickness reached at the end of the etching in step iii)).

The micro-structured monocrystalline silicon material 10 is finally cleaned (step iv)) both of the sacrificial layer islets 2a and of the layer 3 of said oxide. For this purpose, use is made of a third etching step of the wet chemical etching type consisting in immersing the micro-structured monocrystalline silicon material 10 in a solution of hydrofluoric acid at a dilution of 100:1, at ambient temperature for a few minutes, typically 2 minutes to 5 minutes, so as to obtain the micro-structured monocrystalline silicon substrate 100 as shown in FIG. 4.

In FIG. 4, each cavity has a bottom portion 4a and a top portion 4b, with the maximum distance between these two portions defining the depth P of said cavity. The bottom section in the bottom portion 4a of the cavity 4 is smaller than the top section in the top portion 4b of the cavity 4, so as to form a V-shaped cavity: the cavities become smaller with increasing depth.

The depth P obtained after step iv) is, on average, about 10 μm.

As shown in FIG. 4, the semiconductor material 1 has been eliminated by more than 90% in volume in order to form said cavities 4, thereby obtaining the micro-structured substrate 100.

In plan view, the top faces 4b of the cavities in the micro-structured monocrystalline silicon substrate 100 occupy no more than 5% of the area of the semiconductor material 1.

Naturally, the overall structure of the cavities formed in the thickness of the layer of monocrystalline silicon material (after step iv)) is substantially uniform: said cavities are of dimensions (e.g. depth) and of shapes (e.g. V-shape) that are substantially identical to one another.

The method of the invention may be continued by doping (step v)) the micro-structured monocrystalline silicon substrate 100 with sulfur, using a beam of sulfur ions (step not shown).

Sulfur is thus implanted by bombarding the surface of the micro-structured monocrystalline silicon substrate 100 with a beam of ionized sulfur ions (S+) that have been accelerated to 40 kilovolts (kV): the maximum density of sulfur is thus located at a depth of about 40 nm from the bombarded surface.

Once step v) has been performed, the resulting concentration of the doping element within the micro-structured monocrystalline silicon substrate is of the order of 1×10¹⁶ atoms/cm³.

In order to restore its initial crystalline structure to the silicon material, or in other words in order to reconstitute the crystal lattice of the silicon in the form of a monocrystalline lattice as existed before doping step v, it is necessary to apply heat treatment thereto. For this purpose, the sulfur-doped and micro-structured monocrystalline silicon substrate 100 is placed in an oven at a temperature of 800° C. for 1 hour or at a temperature of 1000° C. for about 10 seconds (step not shown).

FIG. 5 shows how optical absorption (%) varies as a function of wavelength (nm) for two semiconductor substrates of the invention (C2 and C3), and for a prior art substrate (C1).

The C1 measurements represent said variation for a non-micro-structured monocrystalline silicon substrate having sulfur doping at 1×10¹⁶ atoms/cm³: only the steps v) and vi) as described in the above example were performed on the surface of a monocrystalline silicon material having a surface that was substantially plane.

The C2 measurements represent said variation for a monocrystalline silicon substrate micro-structured by the method of the invention and not doped with sulfur: only steps i) to iv) were performed, as described in the above-mentioned example.

The C3 measurements represent said variation for a monocrystalline silicon substrate micro-structured by the method of the invention with sulfur doping at 1×10¹⁶ atoms/cm³: steps i) to vi) were performed as described in the above-mentioned example.

Looking at these measurements summarized in the table of FIG. 5, it can clearly be seen that the micro-structured monocrystalline silicon substrate obtained by the method of the invention (steps i) to iv)) (C2) presents very good absorption properties compared with a non-micro-structured monocrystalline silicon substrate (C1), even when the non-micro-structured substrate has been doped with sulfur. The substrate C2 presents absorption lying in the range 15% to 25% for wavelengths in the range 1200 nm to 2000 nm, while the substrate C1 presents absorption of less than 10% for wavelengths lying in the range 1200 nm to 2000 nm.

It can also be seen that adding steps v) and vi) to the method of the invention (steps i) to iv)) (C3) serves to improve the absorbance properties of the substrate significantly since absorption is obtained that lies in the range 25% to 35% for wavelengths lying in the range 1200 nm to 2000 nm.

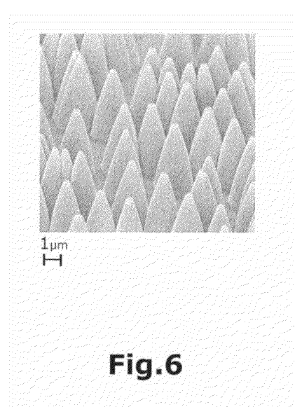

FIG. 6 shows an SEM image of the surface of a structured semiconductor substrate obtained by the method of the invention. This image shows the structured semiconductor substrate as obtained after performing steps i) to iv) as described above with reference to FIGS. 1 to 4.

In FIG. 6, the residual portions of semiconductor material constituting sloping walls of said cavities are conical in shape (i.e. conical portions), and more particularly they are of the “fairy chimney type”.

The distance between the tops of two immediately adjacent conical portions is in particular no more than 10 μm, and more particularly said distance lies in the range 1 μm to 5 μm.

1. A method of fabricating a structured semiconductor substrate, said method comprising the steps of:
i) depositing on the surface of a semiconductor material, a sacrificial layer of material different from the semiconductor material;
ii) etching the sacrificial layer formed in step i) at least in part so as to form sacrificial layer islets on the surface of the semiconductor material;
iii) etching the semiconductor material of step ii), at least in part, in zones that are not protected by said islets, so as to form a structured semiconductor material, this step iii) being performed in the presence of oxygen so as to deposit an oxide layer on the surface of the semiconductor material; and
iv) eliminating the sacrificial layer islets and the oxide layer from the surface of the semiconductor material obtained in step iii), so as to form said structured substrate.

2. A method according to claim 1, wherein the semiconductor material is silicon.

3. A method according to claim 1, wherein the sacrificial layer of step i) is selected from a layer of an oxide and a layer of a nitride.

4. A method according to claim 3, wherein the oxide layer is a layer of silicon oxide (SiO₂).

5. A method according to claim 3, wherein the layer of nitride is a layer of silicon nitride (Si₃N₄).

6. A method according to claim 1, wherein the etching of step ii) is reactive ionic etching.

7. A method according to claim 1, wherein the etching of step iii) is reactive ionic etching.

8. A method according to claim 1, wherein step iv) is performed in the presence of a solution of hydrofluoric acid (HF).

9. A method according to claim 1, wherein the etching of step ii) is anisotropic etching.

10. A method according to claim 1, wherein the etching of step iii) is anisotropic etching.

11. A method according to claim 1, wherein the structured substrate is a substrate having its surface including cavities with sloping walls, thereby forming an array of cavities.

12. A method according to claim 1, wherein said method further includes the following step:
v) doping the substrate obtained in step iv) with a doping element selected from the group consisting of sulfur, selenium, and tellurium, or a mixture thereof.

13. A method according to claim 12, wherein the concentration of the doping element in step v), within the semiconductor material, lies in the range 1×10¹⁶ atoms/cm³ to 1×10²⁰ atoms/cm³.

14. A method according to claim 12, wherein said method further includes the following step:
vi) performing heat treatment to electrically activate the doping element within the substrate of step v).

15. A method according to claim 14, wherein the heat treatment in step vi) is performed at a temperature lying in the range 500° C. to 1200° C. (limits included).
